(19) United States
(12) Patent Application Publication
(10) Pub. No.: US 2026/0344103 A1
(43) Pub. Date: Oct. 29, 2026

(54) SEMICONDUCTOR DEVICE

(71) Applicant: EPISTAR CORPORATION, Hsinchu (TW)

(72) Inventors: Wei-Long Chen, Hsinchu (TW); Chu-Jih Su, Hsinchu (TW); Chao-Shun Huang, Hsinchu (TW); Chang Da Tsai, Hsinchu (TW); Shih-Chang Lee, Hsinchu (TW)

(21) Appl. No.: 19/188,476

(22) Filed: Apr. 24, 2025

(51) Int. Cl. H10F 77/20; H10F 30/22; H10F 77/30

(52) U.S. Cl. CPC H10F 77/206; H10F 30/22; H10F 77/306

(57) ABSTRACT

The present disclosure provides a semiconductor device, including a first semiconductor layer, a second semiconductor layer, an active region located between the first semiconductor layer and the second semiconductor layer and an electrode structure located on the second semiconductor structure. The second semiconductor layer includes a modified region with a perimeter and an un-modified region surrounding the modified region. The electrode structure includes a first extending segment and a second extending segment which are physically separated from each other. The first extending segment and the second extending segment do not overlap with the un-modified region in a vertical direction.

### TECHNICAL FIELD

The present disclosure relates to a semiconductor device, and particularly to a semiconductor light-detecting device.

### DESCRIPTION OF BACKGROUND ART

Semiconductor devices have been extensively adopted in daily life. III-V compound semiconductor, such as GaP, InGaAs or GaN, has favorable optoelectronic characteristics for integrated circuit (IC), light-emitting diode (LED), laser diode, photovoltaic cell (PVC) or photodiode. LED is capable of transforming electricity into light, and is a common light resource widely used in the fields of display, lighting and communication. Photodiode is capable of transforming light into electricity, and is widely used in the field of ambient light sensing, communication, ranging, security and physiological monitoring. As the functions of electronic devices become more complex, photodiodes are developing in the direction of miniaturization, and the requirements for sensing capabilities and noise reduction are getting higher and higher.

### SUMMARY OF THE DISCLOSURE

The present disclosure provides a semiconductor device, including a first semiconductor layer, a second semiconductor layer, an active region located between the first semiconductor layer and the second semiconductor layer and an electrode structure located on the second semiconductor structure. The second semiconductor layer includes a modified region with a perimeter and an un-modified region surrounding the modified region. The electrode structure includes a first extending segment and a second extending segment which are physically separated from each other, and the first extending segment and the second extending segment do not overlap with the un-modified region in a vertical direction in a vertical direction.

The present disclosure also provides a package module. The package module includes a carrier, a light emitting device and a semiconductor device.

### BRIEF DESCRIPTION OF THE DRAWINGS

The foregoing aspects and many of the attendant advantages of the present disclosure will become more readily appreciated as the same becomes better understood by reference to the following detailed description, when taken in conjunction with the accompanying drawings, wherein:

FIG. 1A shows a top view of a semiconductor device disclosed in accordance with one embodiment of the present disclosure;

FIG. 1B shows a cross-sectional view of the semiconductor device along A-A′ line in FIG. 1A;

FIG. 1C shows a cross-sectional view of the semiconductor device along B-B′ line in FIG. 1A;

FIG. 1D shows an enlarged view of region C in FIG. 1A;

FIG. 2A shows a top view of a semiconductor device in accordance with one embodiment of the present disclosure;

FIG. 2B shows a top view of a semiconductor device in accordance with one embodiment of the present disclosure

FIG. 3 shows a schematic view of a package module in accordance with one embodiment of the present disclosure.

### DETAILED DESCRIPTION OF PREFERRED EMBODIMENTS

Exemplary embodiments of the present disclosure will be described in detail with reference to the accompanying drawings hereafter. The following embodiments are given by way of illustration with Cartesian Coordinates (X, Y, Z axes) to help those skilled in the art fully understand the spirit of the present disclosure. Hence, it should be noted that the present disclosure is not limited to the embodiments herein and can be realized in various forms. Further, the drawings are not precise scale and components may be exaggerated in view of width, height, length, etc. Herein, the similar or identical reference numerals will denote the similar or identical components throughout the drawings. In the embodiments of the present disclosure, if not described otherwise, the term “horizontal” means any value or vector along X-axis, Y-axis or on X-Y plane, while the term “vertical” means any value or vector along Z-axis.

In addition, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

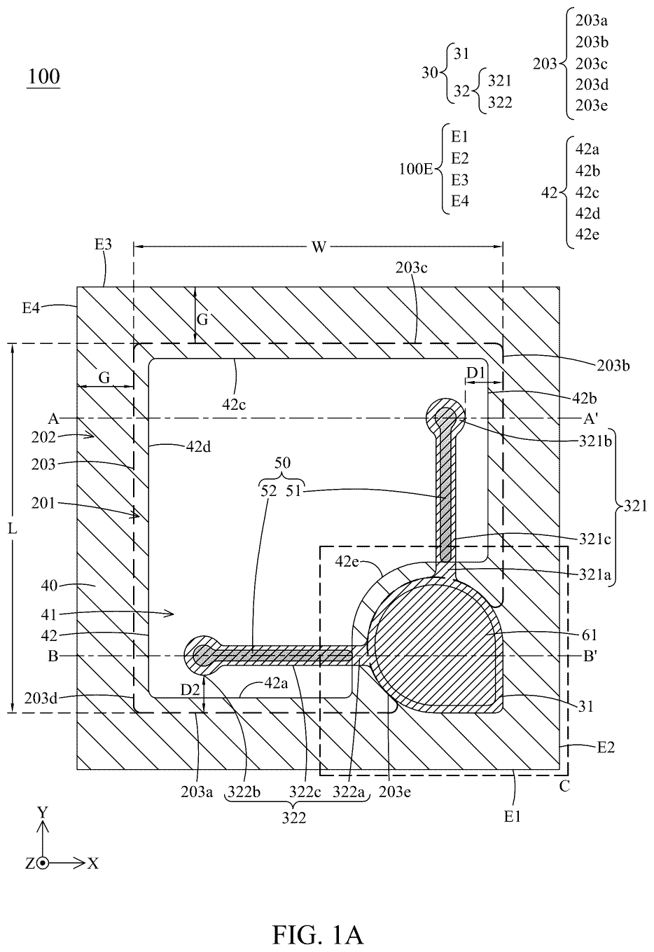

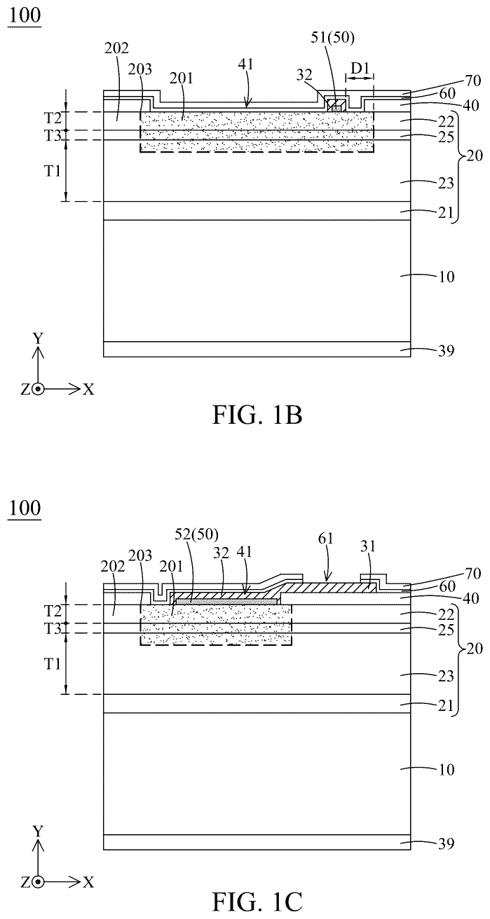

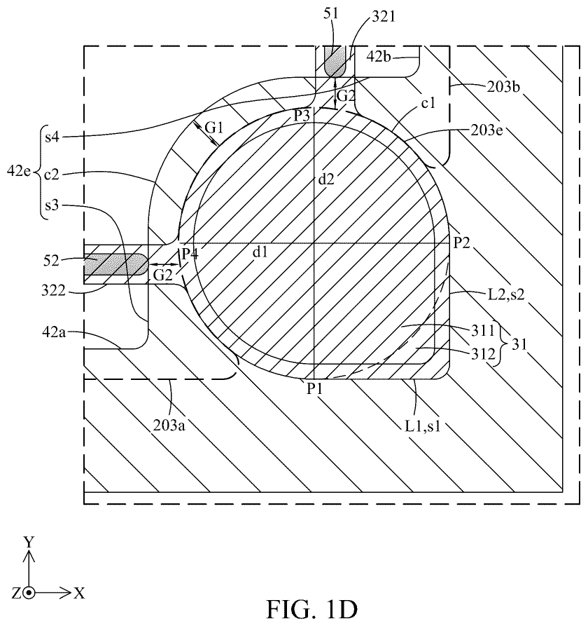

FIG. 1A shows a top view of a semiconductor device 100 disclosed in accordance with one embodiment of the present disclosure. FIGS. 1B and 1C are cross-sectional views of the semiconductor device 100 respectively along A-A′ line and B-B′ line in FIG. 1A. FIG. 1D is an enlarged top view of region C in FIG. 1A.

The semiconductor device 100 can be implemented in any shapes, such as polygon, circle and irregular shape. As shown in FIG. 1A, in this embodiment, the semiconductor device 100 has a first perimeter 100E formed in a rectangle shape, and the first perimeter 100E includes four sides E1, E2, E3, E4. The side E1 and the side E3 connect to the side E2 and the side E4. In this embodiment, the side E1 and the side E3 are parallel to X-axis, and the side E2 and the side E4 are parallel to Y-axis. In some embodiments, the four sides E1, E2, E3, E4 may respectively have a length equal to or smaller than 400 μm.

The semiconductor device 100 can be a light-emitting diode, a laser diode or a photodiode to conduct photoelectric or optoelectronic conversion. As shown in FIGS. 1A-1C, the semiconductor device 100 includes a semiconductor stack 20, a first electrode structure 30 and a second electrode structure 39. The first electrode structure 30 and the second electrode structure 39 are separated from each other and both connect to the semiconductor stack 20. In some embodiments, the semiconductor device 100 can optionally include a base 10, a protecting layer 40, a contact structure 50, an anti-reflection layer 60 and/or a filter structure 70.

The base 10 is located beneath the semiconductor stack 20, and provides the mechanical strength to support the semiconductor device 100. In some embodiments, the base 10 can be a growth substrate for growing the semiconductor stack 20 thereon. In another embodiment, the base 10 can be a supporting substrate to support the semiconductor stack 20, and the semiconductor stack 20 may be connected to the base 10 through a bonding structure (not shown).

The semiconductor stack 20 includes a first semiconductor layer 21 adjacent to the base 10, a second semiconductor layer 22 away from the base 10, and an active region 23 located between the first semiconductor layer 21 and the second semiconductor layer 22. The first semiconductor layer 21 and the second semiconductor layer 22 can have same or different materials, and the active region 23 can have a material different from that of the first semiconductor layer 21 and/or the second semiconductor layer 22. The first semiconductor layer 21 has a first dopant, and the second semiconductor layer 22 has a second dopant. The first dopant and the second dopant can be the same or different, and the first semiconductor layer 21 and the second semiconductor layer 22 can have the same or different conductivity types. In some embodiments, the first semiconductor layer 21 with the first dopant has a first conductivity type, and the second semiconductor layer 22 with the second dopant has a second conductivity type opposite to the first conductivity type. The first conductivity type and the second conductivity type can be n-type and p-type, or p-type and n-type. The first semiconductor layer 21 has the first dopant with a first doping concentration, and the second semiconductor layer 22 has the second dopant with a second doping concentration. In some embodiments, the first doping concentration and/or the second doping concentration can be between 10¹⁷/cm³ to 5×10¹⁸/cm³.

The active region 23 can be un-doped or unintentionally-doped. The term “unintentionally-doped” means the active region 23 may have the first dopant and/or the second dopant. Generally, for the un-doped or unintentionally-doped active region 23, a doping concentration thereof is less than 10¹⁶/cm³. The active region 23 can be a single-layer or multi-layer structure.

As shown in FIG. 1B, the semiconductor stack 20 can further include a modified region 201 and an un-modified region 202. More specifically, the modified region 201 is formed in the second semiconductor layer 22 by adding a third dopant into a specific region of the second semiconductor layer 22, and the third dopant is different from the first dopant and the second dopant. For example, in the second semiconductor layer 22, the modified region 201 includes the both the second dopant and the third dopant, and the un-modified region 202 includes the second dopant without the third dopant. The third dopant in the modified region 201 has a third doping concentration larger than the second doping concentration, so that the modified region 201 has the second conductivity type. In some embodiments, the third doping concentration can be between 2×10¹⁷/cm³ to 5×10¹⁹/cm³. When the semiconductor stack 20 includes the modified region 201, both the first semiconductor layer 21 with the first dopant and the second semiconductor layer 22 with the second dopant have the first conductivity type, and the modified region 201 with the third dopant has the second conductivity type, so that the semiconductor stack 20 forms a p-i-n structure.

The base 10, the first semiconductor layer 21, the second semiconductor layer 22 and the active region 23 can respectively include III-IV compound semiconductor, such as GaAs, InGaAs, AlGaAs, AlInGaAs, AlInAs, GaP, InP, InGaP, AlInP, AlGaInP, GaN, InGaN, AlGaN, AlInGaN, AlAsSb, InGaAsP, InGaAsN, or AlGaAsP. The first dopant, the second dopant, and the third dopant can respectively be zinc (Zn), beryllium (Be), magnesium (Mg), carbon (C), silicon (Si), germanium (Ge), tin (Sn), sulfur(S), selenium (Se), or tellurium (Te).

As shown in FIGS. 1A-1C, the first electrode structure 30 is disposed on a top surface of the second semiconductor layer 22 and forms electrical connection with the modified region 201. The second electrode structure 39 is disposed on a bottom surface of the base 10 and forms electrical connection with the first semiconductor layer 21 through the base 10. When the semiconductor device 100 is a photodiode, a top surface of the second semiconductor layer 22 can be a light receiving surface. In that case, an incident light enters the semiconductor device 100 through the top surface of the second semiconductor layer 22, and is absorbed by the active region 23 to generate electrons and holes. By applying bias to the semiconductor stack 20, the electrons and holes (or the holes and electrons) move towards the first semiconductor layer 21 and the modified region 201 respectively and collected by the first electrode structure 30 and the second electrode structure 39 to form a photocurrent. Thus, the semiconductor device 100 is capable of outputting electric signals (photocurrent) to an external circuit or an external device through the first electrode structure 30 and the second electrode structure 39.

As shown in FIG. 1A, the modified region 201 has a second perimeter 203, and a region which is beyond the second perimeter 203 without the third dopant can be defined as the un-modified region 202. The modified region 201 can be formed by diffusion process or ion implantation process. In some embodiments, the modified region 201 can further optionally extend into the active region 23. As shown in FIGS. 1B and 1C, the third dopant is diffused into a part of the active region 23 adjacent to the second semiconductor layer 22 so that the modified region 201 also forms in the active region 23. Forming the modified region 201 into the active region 23 may be beneficial to reduce dark current and improve signal-to-noise ratio (S/N) of the semiconductor device 100.

As shown in FIG. 1A, the modified region 201 is surrounded by the un-modified region 202, and has a width W along X-axis and a length L along Y-axis. The width W and the length L can be the same or different. In some embodiments, the width W and the length L can be between 200 μm to 350 μm, respectively. The second perimeter 203 is located within the first perimeter 100E of the semiconductor device 100, and includes four side portions 203a, 203b, 203c, 203d and a first corner portion 203e. The four side portions 203a, 203b, 203c, 203d respectively correspond to the four sides E1, E2, E3 and E4 of the first perimeter 100E, and the first corner portion 203e connects the side portions 203a, 203b. In some embodiments, the four side portions 203a, 203b, 203c, 203d and the corresponding four sides E1, E2, E3, E4 of the first perimeter 100E is separated from each other by a gap G in a range of 20 μm to 30 μm. The modified region 201 has a first area A1. In some embodiments, the first area A1 can be in a range of 20000 μm² to 63000 μm².

The active region 23 has a first bandgap Eg1 and a first cutoff wavelength λ1, and is capable of absorbing the light with a wavelength equal to or smaller than the first cutoff wavelength λ1. The second semiconductor layer 22 has a second bandgap Eg2 and a second cutoff wavelength λ2, and is capable of absorbing the light with a wavelength equal to or smaller than the second cutoff wavelength λ2. For example, when the first bandgap Eg1 (or second bandgap Eg2) is 3.1 eV, the active region 23 (or the second semiconductor layer 22) can absorb light with a wavelength less than about 400 nm, such as ultraviolet light. When the first bandgap Eg1 (or second bandgap Eg2) is 2.14 eV, the active region 23 (or the second semiconductor layer 22) can absorb light with a wavelength less than about 580 nm, such as ultraviolet light, blue light and green light. When the first bandgap Eg1 (or second bandgap Eg2) is 0.73 eV, the active region 23 (or the second semiconductor layer 22) can absorb light with a wavelength less than about 1700 nm, such as ultraviolet light, blue light, green light, red light and infrared light.

In some embodiments, the second bandgap Eg2 of the second semiconductor layer 22 can be larger than the first bandgap Eg1 of the active region 23, and the second cutoff wavelength λ2 of the second semiconductor layer 22 is smaller than the first cutoff wavelength λ1 of the active region 23. Assuming the incident light includes a first component with a wavelength smaller than the second cutoff wavelength λ2 and a second component with a wavelength between the second cutoff wavelength λ2 and the first cutoff wavelength λ1, the second semiconductor layer 22 can absorb the first component, and the active region 23 can absorb both the first component and the second component. As the incident light enters the semiconductor stack 20 from the light receiving surface, the first component will be absorbed by the second semiconductor layer 22 and the second component will penetrate through the second semiconductor layer 22 and be absorbed by the active region 23 to generate the photocurrent. In other words, most of the light absorbed by the active region 23 has a wavelength in the range between the first cutoff wavelength λ1 and the second cutoff wavelength λ2, and the range can be define as a target wavelength range of the semiconductor device 100. In some embodiments, the light outside the target wavelength range (i.e. the first component of the incident light) may pass the second semiconductor layer 22 and be absorbed by the active region 23, and the photocurrent generated thereby can be considered as noise.

The target wavelength range can be adjusted by selecting the first bandgap Eg1 and the second bandgap Eg2. For example, the semiconductor device 100 is designed to detect light with wavelength from 1300 nm to 1600 nm, and then the first bandgap Eg1 of the active region 23 can not be greater than 0.77 eV (λ1~1600 nm) and the second bandgap Eg2 of the second semiconductor layer 22 can not be greater than 0.96 eV (λ2~1300 nm). Through making the second bandgap Eg2 larger than the first bandgap Eg1, noises caused by the incident light out of the target wavelength range can be reduced.

In a vertical direction (along Z-axis), the active region 23 and the second semiconductor layer 22 respectively have a first thickness T1 and a second thickness T2. In some embodiments, the first thickness T1 can be in a range of 1000 nm to 4000 nm to get identified electric signals (photocurrent) caused by the light absorption of the active region 23. In some embodiments, the second thickness T2 can be equal to or greater than 500 nm and less than 2000 nm for reducing noise caused by the incident light out of the target wavelength range absorbed by the active region 23.

The semiconductor stack 20 can optionally include a barrier layer 25 located between the second semiconductor layer 22 and the active region 23. The barrier layer 25 can block the electrons or the holes, which are generated by light absorption in the second semiconductor layer 22, moving from the second semiconductor layer 22 to the active region 23. In some embodiments, the barrier layer 25 has a third bandgap Eg3 larger than the second bandgap Eg2 of the second semiconductor layer 22 and the first bandgap Eg1 of the active region 23 to block the electrons or holes from the second semiconductor layer 22. Referring the FIGS. 1B and 1C, the modified region 201 is formed in second semiconductor layer 22, the barrier layer 25 and the active region 23. The barrier layer 25 has a third thickness T3 in the vertical direction (Z-axis), and the third thickness T3 is smaller than the first thickness T1 and/or the second thickness T2. In some embodiments, the third thickness T3 is in a range of 10 nm to 500 nm.

The barrier layer 25 can include III-IV compound semiconductor, such as GaAs, InGaAs, AlGaAs, AlInGaAs, AlInAs, GaP, InP, InGaP, AlInP, AlGaInP, GaN, InGaN, AlGaN, AlInGaN, AlAsSb, InGaAsP, InGaAsN or AlGaAsP.

Referring to FIGS. 1A to 1C, the protecting layer 40 is disposed on the second semiconductor layer 22, and is transparent for the incident light to pass. As shown in FIG. 1A, the protecting layer 40 includes an opening 41 defined by an inner wall 42, and the opening 41 and the inner wall 42 are within the second perimeter 203 of the modified region 201 to expose a part of the modified region 201. In other words, the protecting layer 40 crosses the second perimeter 203 and covers a part of the modifier region 201 to further reduce dark current.

As shown in FIG. 1A, the inner wall 42 of the protecting layer 40 has four edge portions 42a, 42b, 42c, 42d and a second corner portion 42e. The four edge portions 42a, 42b, 42c, 42d respectively correspond to the four side portions 203a, 203b, 203c, 203d of the second perimeter 203. The second corner portion 42e connect the edge portion 42a and the edge portion 42b and corresponds to the first corner portion 203e of the second perimeter 203.

The protecting layer 40 can be a single-layer or multi-layer structure. The protecting layer 40 can include insulating materials, such as tantalum oxide (TaOx), aluminium oxide (AlOx), silicon oxide (SiOx), titanium oxide (TiOx), silicon nitride (SiNx), silicon oxynitride (SiOxNy), niobium pentoxide (Nb₂O₅) or spin-on glass (SOG).

The first electrode structure 30 is disposed on the protecting layer 40 and the second semiconductor layer 22. Referring to FIGS. 1A to 1C, the first electrode structure 30 includes a pad portion 31 disposed on the protecting layer 40 and an extension portion 32 connecting the pad portion 31. The extension portion 32 is disposed on and connected to the modified region 201, so that the first electrode structure 30 forms electrical connection with the modified region 201. The extension portion 32 includes a first extending segment 321 and a second extending segment 322 which are physically separated from each other and connected to the pad portion 31.

As shown in FIGS. 1A to 1C, in the vertical direction (along Z-axis), the first extending segment 321 and the second extending segment 322 are overlapped with the modified region 201 without overlapping with the un-modified region 202. In other words, the first extending segment 321 and the second extending segment 322 do not connect the un-modified region 202. In other embodiments, the extension portion 32 can optionally include more extending segments, such as a third extending segment and/or a fourth extending segment (not shown).

The first electrode structure 30 and the second electrode structure 39 can include metals or alloys, such as aluminum (Al), chromium(Cr), copper (Cu), tin (Sn), gold (Au), nickel (Ni), titanium (Ti), platinum (Pt), lead (Pb), zinc (Zn), cadmium (Cd), antimony (Sb), cobalt (Co), beryllium (Be), germanium (Ge), or alloys of abovementioned metals, such as GeAuNi, BeAu, GeAu or ZnAu.

Referring to FIGS. 1A and 1D, the first extending segment 321 includes a first end 321a connecting the pad portion 31, a second end 321b away from the pad portion 31, and a first connecting part 321c connecting the first end 321a and the second end 321b. The second extending segment 322 includes a third end 322a connecting the pad portion 31, a fourth end 322b away from the pad portion 31, and a second connecting part 322c connecting the third end 322a and the fourth end 322b. The first end 321a and the third end 322a are located on the protecting layer 40 without contacting the modified region 201. The second end 321b, the first connecting part 321c, the fourth end 322b and the second connecting part 322c contact the modified region 201 through the opening 41. As shown in FIG. 1A, the second end 321b of the first extending segment 321 and the fourth end 322b of the second extending segment 322 can be formed in a round shape to avoid tip discharging issue.

In this embodiment, the second end 321b has a width larger than or equal to that of the first end 321a. The fourth end 322b has a width larger than or equal to that of the third end 322a. The first connecting part 321c and/or the second connecting part 322c can be straight or curved. When the first connecting part 321c and the second connecting part 322c are straight, the first extending segment 321 and the second extending segment 322 can extend along a first horizontal direction and a second horizontal direction, respectively. The first horizontal direction is different from the second horizontal direction. For example, the first horizontal direction and the second horizontal direction can be Y-axis and X-axis, or X-axis and Y-axis.

When the top surface of the second semiconductor layer 22 is the light receiving surface of the semiconductor device 100, the extension portion 32 disposed on the modified region 201 may blocks the incident light and reduces the responsivity. In some embodiments, the extension portion 32 have a second area A2, and the difference between the first area A1 of the modified region 201 and the second area A2 can be defined as an effective light absorbing area of the semiconductor device 100. Generally, the extension portion 32 of the first electrode structure 30 may have a ring shape (not shown) for good photocurrent extraction uniformity. In the present disclosure, forming the extension portion 32 of the first electrode structure 30 in two separated segments which reduces the second area A2 can maintain photocurrent extraction uniformity. Thus, the effective light absorbing area is enlarged and the photocurrent output of the semiconductor device 100 is improved. In some embodiments, the second area A2 is 6% to 20% of the first area A1.

As shown in FIGS. 1A and 1B, the first extending segment 321 and the second extending segment 322 are separated from the four side portions 203a, 203b, 203c, 203d of the second perimeter 203. The shortest distance between the first extending segment 321 and the four side portions 203a, 203b, 203c, 203d can be defined as a first distance D1, and the shortest distance between the second extending segment 322 and the four side portions 203a, 203b, 203c, 203d can be defined as a second distance D2. The first distance D1 and the second distance D2 can be the same or different. As shown in FIG. 1A, the first distance D1 is between the second end 321b of the first extending segment 321 and the side portion 203b, and the second distance D2 is between the fourth end 322b of the second extending segment 322 and the side portion 203a. In some embodiments, to avoid loss of photocurrent extraction uniformity, a ratio of the first distance D1 to the width W of the modified region 201 and/or a ratio of the second distance D2 to the length L of the modified region 201 can be between 0.07 to 0.26, such as 0.1, 0.15 or 0.2. In some embodiments, the first distance D1 and/or the second distance D2 can be in a range of 25 μm to 65 μm.

Referring to FIGS. 1A, 1C and 1D, the pad portion 31 is disposed close to a corner between the side E1 and the side E2. The pad portion 31 includes a main part 311 and a first corner part 312. The main part 311 is a circle and has a first diameter d1 parallel to X-axis and a second diameter d2 parallel to Y-axis. The first diameter d1 and the second diameter d2 intersect with a circumference of the main part 311 at points P1, P3, P2 and P4. That is, the circumference of the main part 311 includes four arcs P1-P2, P2-P3, P3-P4, P1-P4. The first corner part 312 extends outwards from the arc P1-P2, and is defined by a tangent line L1 of the point P1, a tangent line L2 of the point P2 and the arc of P1-P2. Thus, the pad portion 31 has a contour including at least two straight sections s1, s2 and a first curved section c1. The first straight section s1 intersects with the second straight section s2, and the first curved section c1 connects to the two straight sections s1, s2, and the first curved section c1 is a part of the circumference of the main part 311, such as an arc of P3-P4, an arc of P1-P4, an arc of P3-P2 or a combination of these arcs. The intersection between the first straight section s1 and the second straight section s2 may be form in a sharp angle (not shown) or an arc shape (as shown in FIGS. 1A and 1D) to avoid tip discharging issue. In some embodiments, the first diameter d1 and the second diameter d2 can be in a range of 80 μm to 100 μm.

In the present disclosure, the main part 311 is used for wire bonding (not shown) and the first corner part 312 can be used for increasing adhesion strength with the protecting layer 40, so the reliability of the semiconductor device 100 can be improved. In some embodiments, to further improve adhesion strength, the pad portion 31 may optionally include a second corner part extending outwards from the arc P1-P4 (not shown) and/or a third corner part extending outwards from the arc P2-P3 (not shown).

As shown in FIGS. 1A & 1D, the pad portion 31 locates on the un-modified region 202 and does not overlap with the modified region 201 in the vertical direction (along Z-axis) to avoid blocking the incident light to enter the modified region 201. As shown in FIG. 1D, the first corner portion 203e of the second perimeter 203 corresponds to a portion of the first curved section c1 of the pad portion 31. In other embodiments, the modified region 201 may extend and partially overlaps with the pad portion 31 in the vertical direction due to lateral diffusion of the third dopant, so that the first corner portion 203e is located under the pad portion 31 (not shown).

In this embodiment, as shown in FIGS. 1A and 1D, the inner wall 42 of the protecting layer 40 is not overlapped with the contour of the pad portion 31 to prevent the pad portion 31 from contacting the modified region 201 and the un-modified region 202. Specifically, as shown in FIG. 1D, the second corner portion 42e includes a second curved section c2, and optionally includes a third straight section s3 and a fourth straight section s4 for connecting the second curved section c2 to the edge portions 42a and 42b, respectively. The second corner portion 42e is separated from the first curved section c1 of the pad portion 31, and can be set to correspond to a portion of the first curved section c1. In some embodiments, the second curved section c2 and the first section c1 may be concentric arcs, and a central angle of the second curved section c2 can be equal to or smaller than a central angle of the first curved section c1. The shortest distance between the first curved section c1 and the second curved section c2 can be defined as a first gap G1. In some embodiments, the first gap G1 is in a range between 5 μm to 20 μm. Similarly, the shortest distance between the first curved section c1 and the third straight section s3 (along X-axis) or between the first curved section c1 and the fourth straight section s4 (along Y-axis) can be defined as a second gap G2. The second gap G2 can be equal to or larger than the first gap G1.

Referring to FIGS. 1A to 1C, the contact structure 50 is located between the semiconductor stack 20 and the first electrode structure 30 in order to lower an operating voltage of the semiconductor device 100. More specifically, the contact structure 50 is disposed on the modified region 201 without contacting the un-modified region 202, and includes a first contact portion 51 and a second contact portion 52 which are disposed between the modified region 201 and the first extending segment 321 and the second extending segment 322, respectively for forming low resistance interfaces. The first contact portion 51 is covered by the first extending segment 321, while the second contact portion 52 is covered by the second extending segment 322. In this embodiment, the first contact portion 51 and the second contact portion 52 are located within the opening 41 of the protecting layer 40, and may not contact the protecting layer 40. In some embodiments, the first contact portion 51 and the second contact portion 52 can be covered by and in contact with the protecting layer 40 (not shown). As shown in FIG. 1A, the first contact portion 51 has a width smaller than that of the first extending segment 321, and the second contact portion 52 has a width smaller than that of the second extending segment 322.

The contact structure 50 and the modified region 201 can has the same conductivity type. The contact structure 50 has the third dopant with a fourth doping concentration. In some embodiments, the fourth doping concentration can be between 8×10¹⁷ to 5×10¹⁹/cm³. In some embodiment, the contact structure 50 may be un-doped or unintentional doped. For the un-doped or unintentionally-doped a contact structure 50, a doping concentration thereof is less than 10¹⁶/cm³. In some embodiments, the contact structure 50 may have a thickness in the vertical direction between 30 nm to 150 nm. The contact structure 50 can include III-IV compound semiconductor, such as GaAs, InGaAs or GaP.

Referring to FIGS. 1B and 1C, the anti-reflection layer 60 is disposed on the second semiconductor layer 22, the protecting layer 40 and the first electrode structure 30, and contacts the modified region 201 through the opening 41 of the protecting layer 40. The anti-reflection layer 60 can reduce reflection of the incident light to improve light absorption and photocurrent output of the semiconductor device 100. The anti-reflection layer 60 can be a passivation layer covering the modified region 201 to reduce dark current and improve reliability of the semiconductor device 100.

The anti-reflection layer 60 can include insulating materials, such as tantalum oxide (TaOx), aluminium oxide (AlOx), silicon oxide (SiOx), titanium oxide (TiOx), silicon nitride (SiNx), silicon oxynitride (SiOxNy), niobium pentoxide (Nb₂O₅) or spin-on glass (SOG). The anti-reflection layer 60 can have a single-layer or multi-layer structure, and a thickness and material thereof can be selected according to the target wavelength range.

The filter structure 70 can be disposed on the second semiconductor layer 22, the protecting layer 40 and the first electrode structure 30 to adjust light wavelength of the incident light entering into the semiconductor device 100. For example, the filter structure 70 may be designed to block the aforementioned first component of the incident light for further reducing noise, or may further block a part of the second component of the incident light for narrowing the wavelength range of the light entering the active region 23 and improving detecting accuracy. In this embodiment, the filter structure 70 is disposed on the anti-reflection layer 60, and a through hole 61 is formed in the anti-reflection layer 60 and the filter structure 70. As shown in FIGS. 1A and 1C, the through hole 61 corresponds to the pad portion 31 and penetrates the anti-reflection layer 60 and the filter structure 70 to expose the pad portion 31, and the pad portion 31 can be connected to the external circuit. In some embodiments, the through hole 61 has an area smaller than that of the pad portion 31.

The filter structure 70 can be a single-layer structure or a multi-layer structure. For example, the filter structure 70 can be a multi-layer dielectric film formed by multiple high refractive index layers and low refractive index layers that are alternately stacked (for example, a combination of TiOx/SiOx or SiOx/SiNx), or a polymer with a specific light absorption spectrum.

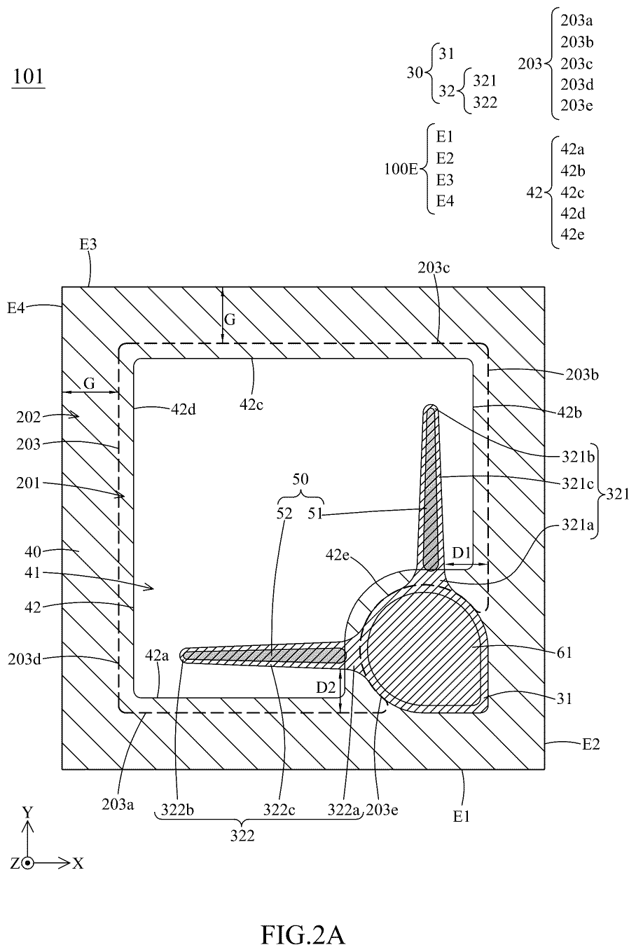

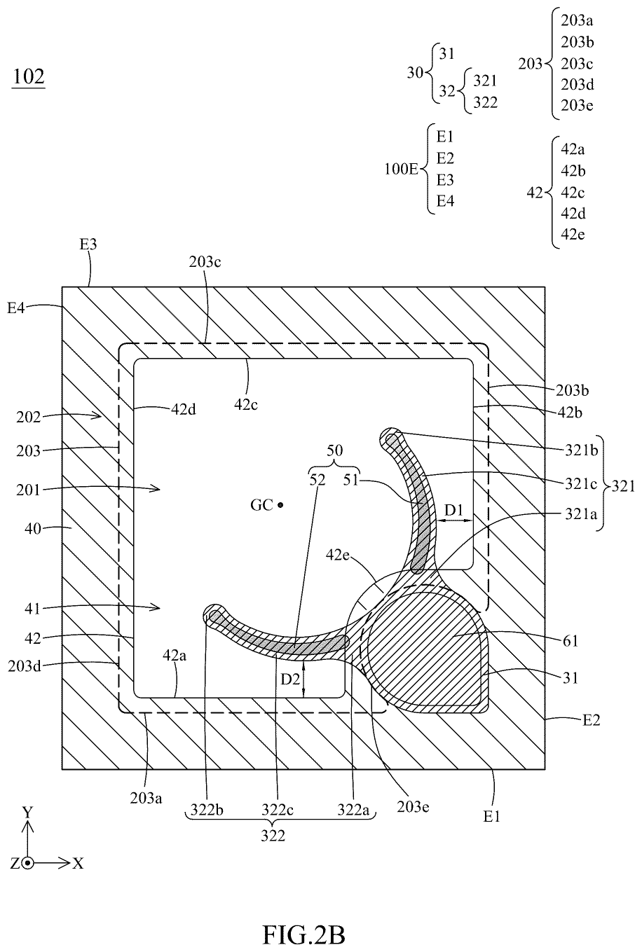

FIG. 2A is a schematic sectional view of a semiconductor device 101 according to some embodiments of the present disclosure. The semiconductor device 101 has a structure similar to the semiconductor device 100, and the first extending segment 321 and/or the second extending segment 322 of the first electrode structure 30 has a design of gradual-changed width. More specifically, the first extending segment 321 has a width gradually reduced from the first end 321a to the second end 321b, and the second extending segment 322 also has a width gradually reduced from the third end 322a to the fourth end 322b. Thus, the first end 321a and/or the third end 322a will not accumulate high current density during operating the semiconductor device 101, and reliability of the semiconductor device 101 can be improved. In some embodiments, the connection between the first end 321a and the pad portion 31 and/or the connection between the third end 322a and the pad portion 31 can be formed in an arc shape instead of a sharp angle to prevent tip discharging issue.

As shown in FIG. 2A, the first contact portion 51 (and/or the second contact portion 52) can also be formed with a gradually changed width corresponding to the first extending segment 321 (and/or the second extending segment 322). The positions, relative relationships, and material compositions of other layers or structures as well as structural variations in the semiconductor device 101 have been described in detail in previous embodiments, and are not repeatedly described herein.

FIG. 2B is a schematic sectional view of a semiconductor device 102 according to some embodiments of the present disclosure. The semiconductor device 102 has a structure similar to the aforementioned semiconductor device 101, and the first extending segment 321 and the second extending segment 322 are formed in an arc shape. As shown in FIG. 2B, the modified region 201 has a geometric center GC. For the first extending segment 321, the second end 321b is closer to the geometric center GC than the first end 321a, and the first connecting part 321c connecting the first end 321a and the second end 321b is curved. Similarly, for the second extending segment 322, the fourth end 322b is closer to the geometric center GC than the third end 322a, and the second connecting part 322c connecting the third end 322a and the fourth end 322b is curved. As such, the first electrode structure 30 can form an opened arc structure surrounding the geometric center GC to further improve photocurrent extraction uniformity of the semiconductor device 102.

Through such electrode design, responsivity of the semiconductor device 102 can be further improved. In some embodiments, a distance between the geometric center GC and the second end 321b and a distance between the geometric center GC and the fourth end 322b are substantially the same. The positions, relative relationships, and material compositions of other layers or structures as well as structural variations in the semiconductor device 102 have been described in detail in previous embodiments, and are not repeatedly described herein.

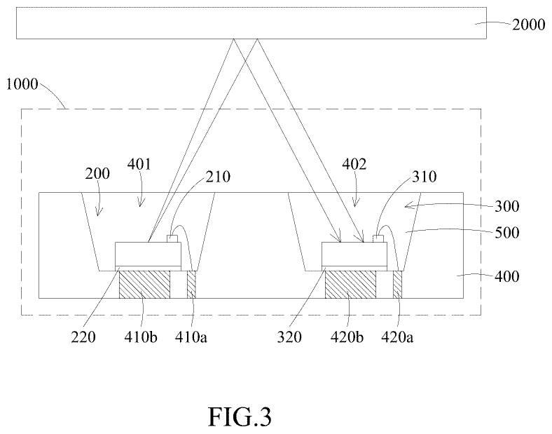

FIG. 3 shows a package module 1000 and the application thereof in accordance with some embodiments of the present disclosure. The package module 1000 includes a light emitting device 200, a light detecting device 300, a carrier 400 and an encapsulation structure 500. The carrier 400 includes a first trench 401 and a second trench 402. The light emitting device 200 and the light detecting device 300 are located in the first trench 401 and the second trench 402 respectively. The encapsulation structure 500 encapsulates the light emitting device 200 and the light detecting device 300 which are in the first trench 401 and the second trench 402. The light detecting device 300 can be the semiconductor devices 100, 101 or 102 described in the previous embodiments or variation embodiments thereof. The light emitting device 200 includes a first connecting electrode 210 and a second connecting electrode 220, and further includes an active layer capable of emitting light with a specific wavelength. The light detecting device 300 includes a third connecting electrode 310 and a fourth connecting electrode 320, i.e. the first electrode structure 30 and the second electrode structure 39 of the semiconductor device 100 mentioned above.

In some embodiments, the light emitting device 200 can emit infrared light with a peak wavelength in a range of 800 nm to 2000 nm, such as 810 nm, 850 nm, 910 nm, 940 nm, 1050 nm, 1070 nm, 1100 nm, 1200 nm, 1300 nm, 1400 nm, 1500 nm, 1600 nm, 1700 nm, 1800 nm or 1900 nm. The wavelength of the light emitted by the light emitting device 200 is within the target wavelength range of the light detecting device 300. The light emitting device 200 and the light detecting device 300 can have the same material, for example, the light emitting device 200 and the light detecting device 300 both include AlInGaAs, AlGaInP, InGaAs and/or InGaAsP.

The carrier 400 includes first circuit structures 410a, 410b electrically connected to the first connecting electrode 210 and the second connecting electrode 220 of the light emitting device 200 respectively to drive the light emitting device 200 to emit the light. The carrier 400 also includes second circuit structures 420a, 420b electrically connected to the third connecting electrode 310 and the fourth connecting electrode 320 of the light detecting device 300 respectively to receive the electrical signal generated by the light detecting device 300.

The carrier 400 can be a package submount or a printed circuit board (PCB). The first to the fourth connecting electrodes 210, 220, 310, 320, the first circuit structures 410a, 410b and the second circuit structures 420a, 420b can include a single-layer or multi-layer structure and include nickel (Ni), titanium (Ti), platinum (Pt), palladium (Pd), silver (Ag), gold (Au), aluminum (Al or copper (Cu). The encapsulation structure 500 can include an organic polymer or inorganic dielectric material, for example, epoxy or silicone.

The package module 1000 may be incorporated in a mobile device, and may be used as a proximity sensor, a structured light scanner or a biosensor. FIG. 3 shows an embodiment of using the package module 1000 as a proximity sensor. When the mobile device including the package module 1000 approaches an object 2000, the light with the specific wavelength emitted by the light emitting device 200 is reflected by the object 2000 to the light detecting device 300, and the electrical signal is generated by the light detecting device 300 for sensing the existence of the object 2000 and triggering an action, e.g. turning on or off the screen of the mobile device accordingly.

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a first semiconductor layer;
a second semiconductor layer located on the first semiconductor layer and comprising a modified region and an un-modified region surrounding the modified region, wherein the modified region has a perimeter;
an active region located between the first semiconductor layer and the second semiconductor layer; and
an electrode structure located on the second semiconductor layer, and comprising a first extending segment and a second extending segment physically separated from the first extending segment;
wherein the first extending segment and the second extending segment do not overlap with the un-modified region in a vertical direction.

2. The semiconductor device according to claim 1, wherein the modified region has a first area, and the first extending segment and the second extending segment have a second area, and a ratio of the second area to the first area is between 6% to 20 %.

3. The semiconductor device according to claim 1, wherein the electrode structure further comprises a pad portion, and the first extending segment comprises a first end connecting the pad portion and a second end away from the pad portion and connecting to the modified region.

4. The semiconductor device according to claim 3, wherein a width of the first end is larger than or equal to that of the second end.

5. The semiconductor device according to claim 3, wherein the first extending segment further comprises a connecting part connecting the first end and the second end, and the connecting part is straight or curved.

6. The semiconductor device according to claim 3, wherein the second end has a round shape, and a width of the second end is larger than that of the first end.

7. The semiconductor device according to claim 3, further comprising a protecting layer located between the electrode structure and the second semiconductor layer, wherein the protecting layer contacts the first end without contacting the second end.

8. The semiconductor device according to claim 1, wherein the electrode structure further comprises a pad portion, and the pad portion comprises a first curved section connecting to the first extending segment and the second extending segment.

9. The semiconductor device according to claim 8, further comprising a protecting layer located between the electrode structure and the second semiconductor layer, and wherein the protecting layer comprises a second curved section corresponding to and separated from the first curved section.

10. The semiconductor device according to claim 9, wherein the second curved section has a central angle equal to or smaller than that of the first curved section.

11. The semiconductor device according to claim 9, wherein a distance between the first curved section and the second curved section is in a range of 5 μm to 20 μm.

12. The semiconductor device according to claim 8, wherein the pad portion is not overlapped with the modified region in the vertical direction, and the perimeter of the modified region comprises a corner portion corresponding to the first curved section of the pad portion.

13. The semiconductor device according to claim 1, further comprising a contact structure located between the electrode structure and the modified region.

14. The semiconductor device according to claim 13, further comprising a protecting layer located between the electrode structure and the second semiconductor layer without contacting the contact structure.

15. The semiconductor device according to claim 13, wherein the contact structure comprises a first contact portion corresponding to the first extending segment and a second contact portion corresponding to the second extending segment.

16. The semiconductor device according to claim 13, wherein the electrode structure further comprises a pad portion connecting the first extending segment and the second extending segment, the contact structure is separated from the pad portion.

17. The semiconductor device according to claim 1, wherein the perimeter of the modified region comprises a plurality of side portions, and a distance between the first extending segment and the closest one of the plurality of side portions is in a range of 25 μm to 65 μm.

18. The semiconductor device according to claim 17, wherein the modified region has a width, and a ratio of the distance between the first extending segment and the closest one of the plurality of side portions to the width is in a range of 0.07 to 0.26.

19. The semiconductor device according to claim 1, wherein the modified region has a width in a range of 200 μm to 350 μm.

20. A package module, comprising:
a carrier;
a light emitting device on the carrier; and
the semiconductor device of claim 1 on the carrier.
